(19) United States
(12) Patent Application Publication
(10) Pub. No.: US 2026/0107456 A1
(43) Pub. Date: Apr. 16, 2026

(54) METHOD OF FORMING 3-DIMENSIONAL MEMORY DEVICE

(71) Applicant: SK hynix Inc., Gyeonggi-do (KR)

(72) Inventors: Sungwon LIM, San Jose, CA (US); Tong ZHANG, San Jose, CA (US); Agus TJANDRA, San Jose, CA (US)

(21) Appl. No.: 18/912,530

(22) Filed: Oct. 10, 2024

(51) Int. Cl. H10B 41/20; H10B 41/35; H10B 43/20; H10B 43/35

(52) U.S. Cl. CPC H10B 41/20; H10B 41/35; H10B 43/20; H10B 43/35

(57) ABSTRACT

A method for forming a multi-site cell structure includes: forming a channel hole extending through a stack of alternating oxide and nitride layers; forming a sacrificial blocking layer to partially fill the channel hole; and separating the sacrificial blocking layer. The forming the sacrificial blocking layer includes depositing the sacrificial blocking layer to have a shape with at least two thicker-thickness areas aligned along a short axis of symmetry of the channel hole and at least two thinner-thickness areas aligned along a long axis of symmetry of the channel hole. The separating the sacrificial blocking layer includes performing an isotropic etching process at least on the sacrificial blocking layer to separate the two at least two thicker-thickness areas of the sacrificial blocking layer by removing the at least two thinner-thickness areas of the sacrificial blocking layer, while remaining the sacrificial blocking layer only at the at least two thicker-thickness areas.

### BACKGROUND

### 1. Technical Field

Embodiments of the present disclosure generally relate to 3-dimensional (“3-D”) semiconductor technology and, more particularly, to multi-site cell (MSC) semiconductor technology.

### 2. Related Art

For increased cell integration (or density) in 3D NAND semiconductor devices, advanced memory cell designs storing multiple bits per cell such as 2 (Multi-Level Cells or MLC), 3 (Triple-Level Cells or TLC), 4 (Quad Level Cells or QLC) and even 5 (Penta Level Cells or PLC) compared to Single Logic Cell (SLC) have been developed. Also, various vertical (100, 200, 300, 400 stacks), lateral (4, 9, 14, 19, 24 rows), and structural (4D, PUA, HWB) scaling methods have been proposed. However, these efforts for increasing integration are reaching their limits in terms of physical limitations and high cost. Hence, additional physical scaling methods are needed. One recently proposed method includes formation of multi-site cells. Examples of MSC method patents include U.S. Pat. No. 11,716,847 B2 to Gao et al. and U.S. Pat. No. 11,545,190 B2 to Choi et al.

### SUMMARY

Embodiments of the present disclosure provide a method of forming a semiconductor device with an MSC structure with at least one channel cut by using a non-conformal sacrificial layer. The inventive method can secure a sufficient channel area which has an adequately large channel cut area while having large enough storage nodes and discrete cells by employing a non-conformal sacrificial layer, i.e., a sacrificial layer with a non-conformal (or uneven) thickness. The method is efficient and effective in providing an MSC with improved structural and performance reliability compared to previous methods.

According to an embodiment, a method for forming a 3-dimensional memory device with a multi-site cell structure is provided, the method comprising providing a stack of alternating oxide layers and nitride layers, forming a channel hole extending through the stack; forming a sacrificial blocking layer to partially fill the channel hole, and separating the sacrificial blocking layer.

The forming of the sacrificial blocking layer may include depositing the sacrificial blocking material to have a shape with at least two thicker-thickness areas aligned along a short axis of symmetry of the channel hole, and at least two thinner-thickness remaining areas aligned along a long axis of symmetry of the channel hole.

The separating of the sacrificial blocking layer may include performing an isotropic etching process to separate the two at least two thicker-thickness areas of the sacrificial blocking layer by removing the at least two thinner-thickness areas of the sacrificial blocking layer and wherein following the isotropic etching process, a thinner sacrificial blocking layer remains only at the previously two thicker thickness areas.

The sacrificial blocking layer may be separated through a wet etching process. The sacrificial blocking layer may be separated through a dry etching process.

The sacrificial blocking layer may include any suitable material, provided it has sufficient dry and wet etching selectivity with the ON stack. For example, the sacrificial blocking layer may include metal oxide, oxide, nitride, un-doped poly-Si (poly-silicon), or metal films, taking into account the materials used for the ON stacks.

The method may further include recessing the tier nitride layers.

The recessing of the tier nitride layers may include continuing the isotropic etching to remove a portion of the nitride layers adjacent to the channel hole to form a pocket area adjacent to the channel pillar.

Each tier nitride layer may be recessed to make the pocket area by selective dry or wet etching using the separated blocking layer as a barrier.

After recessing of the nitride layers, the separated sacrificial blocking layer may be removed by etching which has selectivity between the separated sacrificial blocking layer and the oxide and nitride layers.

The method may further comprise sequentially depositing a blocking oxide layer and a storage layer, both on the pocket area and a sidewall area of the channel hole. The method may further comprise, after the deposition of the storage layer performing oxidation of the storage layer to convert all of the storage layer that is disposed in the channel hole and only a portion of the storage layer that is disposed in the pocket area into an oxidized storage layer while leaving a non-oxidized portion of the storage layer in the pocket area.

The oxidized storage layer may then be removed with selective etching to expose a portion of the blocking oxide layer in the pocket area, the blocking oxide layer on the sidewall of the channel hole, and the non-oxidized portion of the storage layer in the pocket area.

The method may further include forming a tunnel oxide layer to cover the exposed non-oxidized portion of the storage layer in the pocket area, the blocking oxide layer in the pocket area, and the blocking oxide layer in the channel hole.

A channel layer may then be formed on the tunnel oxide layer to fill a remaining area of the pocket area and partially fill the channel hole. A cover layer may then be formed on the channel layer with a non-conformal thickness. The method may further include separating the cover layer while leaving a remaining cover layer only in at least two thicker thickness areas of the cover layer and exposing the channel layer by removing at least two thinner-thickness areas of the cover layer.

The method may further include a channel layer cut by removing the exposed channel layer, and stripping the remaining cover layer.

The method may further comprise, after the removing of the remaining cover layer, gap-filling the channel hole with an oxide, exhuming the nitride layers, and performing metallization in areas where the nitride layers are exhumed to form word lines. The channel hole may have an oval cross-section.

According to another embodiment of the present invention, the method for forming a 3-dimensional memory device with a multi-site cell structure may comprise: providing a stack of alternating oxide layers and nitride layers; forming a channel hole passing through the stack, the channel hole having an oval cross-section with two opposite wide sides aligned along a short axis of symmetry of the oval shape channel hole, and two opposite narrow sides aligned along a long axis of symmetry of the oval shape channel hole; forming a sacrificial blocking layer having a non-conformal thickness to cover a sidewall of the channel hole; separating the sacrificial blocking layer; and recessing the nitride layers by removing a portion of the nitride layers adjacent to the channel hole to form a pocket area.

The separating of the sacrificial blocking layer includes performing an isotropic etching process on the sacrificial blocking layer to separate the two thicker-thickness areas of the sacrificial blocking layer by removing the two thinner-thickness areas of the sacrificial blocking layer. After performing the isotropic etching process, the sacrificial blocking layer remains only at the two thicker-thickness areas.

The method may further comprise recessing the nitride layers by continuing the isotropic etching to remove a portion of the nitride layers adjacent to the channel hole to form a pocket area while using the separated sacrificial blocking layer as a barrier.

The thickness of the sacrificial blocking layer at a center of each of the narrow areas of the channel hole is thinner than a thickness of the sacrificial blocking layer at a center of each of the wide areas of the channel hole.

After the recessing of the nitride layers, the separated sacrificial blocking layer is removed by etching which has selectivity between the separated sacrificial blocking layer and the oxide and nitride layers.

The method may further comprise sequentially depositing a blocking oxide layer and a storage layer, both on the pocket area and a sidewall area of the channel hole and, after the deposition of the storage layer, performing a controlled oxidation of the storage layer to convert all of the storage layer that is disposed in the channel hole and only a portion of the storage layer that is disposed in the pocket area into an oxidized storage layer.

The method may further include removing the oxidized storage layer via selective etching and leaving a non-oxidized portion of the storage layer disposed in the pocket area, forming a tunnel oxide layer to cover the non-oxidized portion of the storage layer storage in the pocket area and in the two thicker-thickness areas of the channel hole; forming a channel layer on the tunnel oxide layer to fill a remaining area of the pocket area and partially fill the two thicker thickness-areas of the channel hole; forming a cover layer on the channel layer in the two thicker-thickness areas of the channel hole; separating the cover layer and exposing the channel layer in the at least two thinner-thickness areas; performing a channel layer cut by removing the exposed channel layer; and removing any remaining cover layer.

The method may further comprise, after the removing of the remaining cover layer gap-filling the channel hole with oxide, exhuming the nitride layers, and performing metallization in areas where the nitride layers are exhumed to form word lines.

### BRIEF DESCRIPTION OF THE DRAWINGS

These and other features and advantages of the present disclosure will become apparent to those skilled in the art of the invention from the following detailed description in conjunction with the following drawings.

FIGS. 1A to 18A, 1B to 18B, and 1C to 18C illustrate a method of forming a discrete-type dual site cell with sacrificial channel cut according to an embodiment of the present disclosure. FIGS. 1A to 18A are plan views of an oval shape channel structure, FIGS. 1B to 18B are cross-sectional views taken along line A-A′ of the corresponding FIGS. 1A to 18A, and FIGS. 1C to 18C are cross-sectional views taken along line B-B′ of the corresponding FIGS. 1A to 18A.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present invention is described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly on the second layer or the substrate.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the invention.

It is further noted, that in the various drawings, like reference numbers designate like elements.

As used herein, singular forms are intended to include the plural forms as well, unless the context clearly indicates otherwise.

According to an aspect of the present disclosure, a method is provided which can significantly improve cell characteristics compared to existing technologies by discretizing a sufficient storage node area recessed through a sacrificial blocking layer and securing a sufficient string current while cutting the channel poly-silicon by a non-conformal sacrificial layer after the channel poly-silicon deposition process for each cell to reduce string current degradation due to the channel cutting operation.

According to an embodiment, a layered structure of alternating layers of oxides (“O”) and nitrides (“N”) is provided, then a channel hole is formed extending through the layered structure along a first axis. The channel hole may have a pillar shape with an oval cross-section. The first axis may be a vertical axis perpendicular to the plane of extension of each of the thin films of the layered structure. At this time, a sacrificial blocking layer having sufficient dry and wet etching selectivity with the ON stack is deposited to partially fill the channel hole.

Then, the tier nitride layers may be recessed. To recess the tier nitride layers, the sacrificial blocking layer may be separated through a wet or dry etching process. The sacrificial blocking layer may be deposited to have a shape with at least two thicker-thickness areas aligned along a short axis and at least two thinner-thickness remaining areas aligned along a long axis. The method makes pocket-type discrete multi-site cells by using the sacrificial layer's deposition characteristics, i.e., a thicker thickness in a less-curvature area aligned along a short axis of the channel hole and a thinner thickness in the more curved areas aligned along a long axis of the channel hole which are also referred to as the corner areas of the channel hole.

The method may further include performing an isotropic etching process to separate the two at least two thicker-thickness areas of the sacrificial blocking layer by removing the at least two thinner-thickness areas of the sacrificial blocking layer. Hence, following the isotropic etching process, the sacrificial blocking layer can remain only at the wider areas.

The isotropic etching is continued to remove a portion of each nitride layer to form a pocket area adjacent to the channel pillar. Each tier nitride layer is recessed to make the pocket area by selective dry or wet etching using the separated blocking layer as a barrier. After the tier nitride recess process, any remaining sacrificial blocking layer is removed by a dry or wet etching process which has enough selectivity between the sacrificial layers and the tier oxide/nitride layers.

Then, a blocking oxide is deposited for providing electrical insulation from the oxide layers and an additional nitride layer that serves as a storage node is deposited at the recessed pocket as well as the pillar sidewall area. The nitride film deposited on the pillar sidewall is removed through the following two methods. First, nitride can be oxidized and oxide film can be removed through wet cleaning. Second, it can also be removed through dry etching which has a sufficient selectivity with both tier oxide and nitride. Then each physically separated storage layer can function as an individual cell.

Afterward, a tunnel oxide is formed by the ONO deposition tool at one time, and then channel poly-silicon is applied in the same manner as the current method. To cut the channel area, sacrificial non-conformal sacrificial layer needs to be deposited. Afterward, the non-conformal sacrificial layer should be separated by a dry or wet separation process at a thinner area instead of a thicker area. Then, the opened channel poly-silicon is removed by a wet cleaning process, and then remaining sacrificial layers need to be removed by dry or wet cleaning which has enough selectivity between channel poly-silicon and tunnel oxide films. Through this process flow, enough total channel area as well as individual channel area in each multi-site cell may be obtained.

In an embodiment, the oxide layers may include word lines WL.

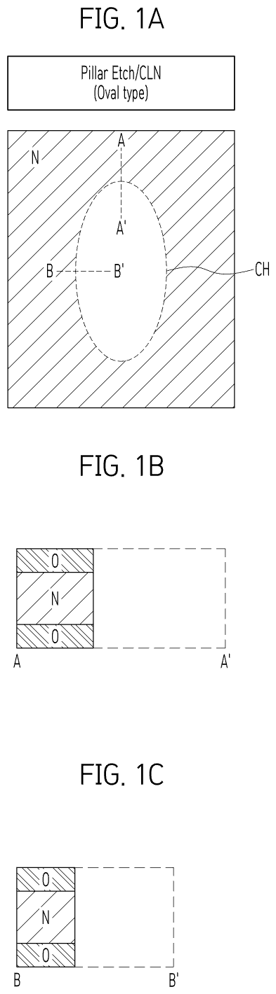

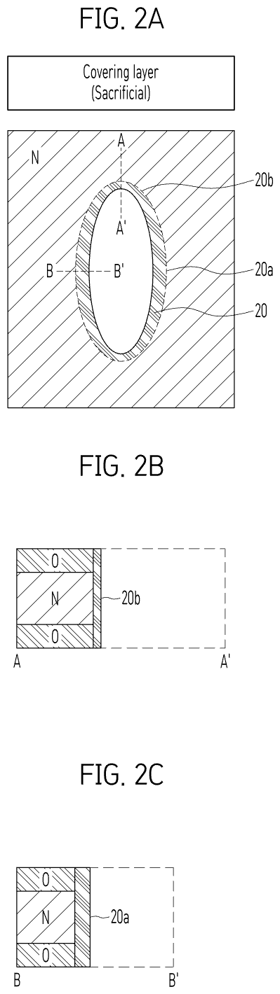

Referring now to FIGS. 1A, 1B, and 1C, the method for forming the MSC includes providing a stack of alternating oxide layers (“O”) and nitride layers (“N”) and forming a channel hole CH extending through the stack. The stack may be referred to as an “ON” stack. The oxide and nitride layers may be thin films of oxides and nitrides, respectively. The channel hole CH may have the form of a pillar with an oval cross-section and may pass through the ON stack along a first axis perpendicular to the ON stack. Because of its oval cross-section the channel hole CH may have a long axis of symmetry and a short axis of symmetry. Referring to FIGS. 2A, 2B, and 2C the method further includes forming a sacrificial blocking layer 20 to partially fill the channel hole CH. The forming of the sacrificial blocking layer 20 may include depositing a sacrificial material such as metal oxide, oxide, nitride, un-doped poly-Si, or metal films as a single, double or triple layer to have a shape with two thicker-thickness areas 20a and two thinner-thickness remaining areas 20b, each of the two thinner-thickness remaining areas 20b being disposed between the two thicker thickness areas 20b. In other words, the thinner-thickness remaining areas 20b may be alternating with the thicker thickness areas 20b. More specifically, the two thicker-thickness areas 20a may be aligned along the short axis of symmetry of the oval shape channel hole, and the two thinner-thickness areas 20ba may be aligned along the long axis of symmetry of the oval shape channel hole.

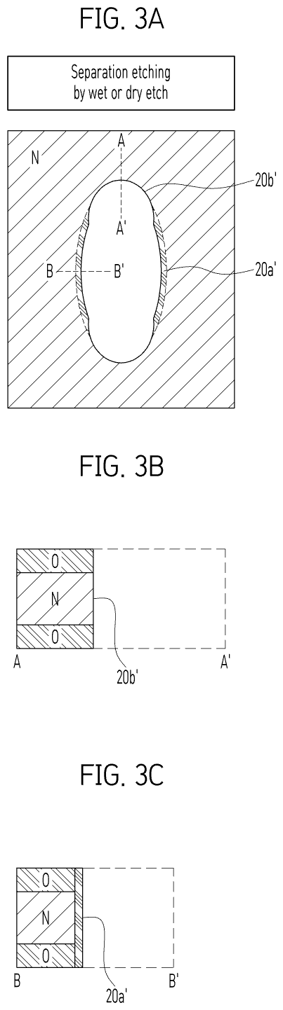

The method further includes separating the sacrificial blocking layer 20 as shown in FIGS. 3A, 3B, and 3C. The separating of the sacrificial blocking layer 20 includes performing an isotropic etching process to separate the two thicker-thickness areas 20a of the sacrificial blocking layer 20 by removing the two thinner-thickness areas 20a of the sacrificial blocking layer. Following the isotropic etching process, thinner sacrificial blocking layer areas 20a′ with a reduced thickness remain only at the previously two thicker thickness areas aligned along a short axis. The previously thinner sacrificial blocking layer areas 20B are removed and in these areas as indicated in FIGS. 3 and 3A with 20B′ the ONO stack structure is exposed. For example, the sacrificial blocking layer 20 may be separated through a wet or dry etching process.

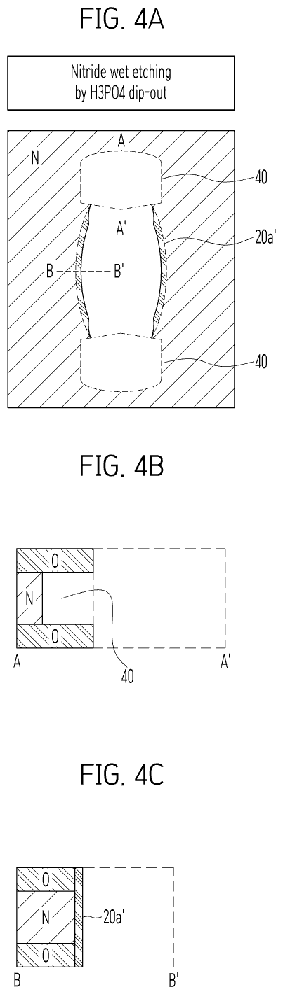

Once the sacrificial blocking layer 20 is separated and the ONO stack is exposed in the 20b′ areas the method further includes recessing the tier nitride layers as illustrated in FIGS. 4A, 4B, and 4CA to form pockets 40 adjacent the channel hole CH. In the illustrated embodiment, a pair of pockets 40 is formed along the long axis of symmetry of the oval shape channel hole CH at each nitride layer. Each pocket 40 may have a generally rectangular shape from a plan view perspective as shown in FIG. 4A.

The recessing of the tier nitride layers “N” and the forming of the pockets 40 may include dry or wet etching o remove a portion of each nitride layer adjacent to the channel hole 20 to form a pair of pockets (also referred to as pocket areas, pocket regions, or simply pockets) adjacent to the channel hole (also referred to as channel pillar or pillar shaped channel hole). For example, a wet etching using phosphoric acid (H3PO4) may be used to remove a portion of the nitride layers in the exposed regions to form the pockets 40. Wet etching may include a dip-out technique which involves dipping the semiconductor wafer into a heated phosphoric acid solution. The etching rate is monitored and controlled and once the desired pockets are formed the wafer is removed from the acid bath and thoroughly rinsed with deionized water to stop the etching and then dried. Hence, the method recesses each tier nitride layer to make the pockets by selective dry or wet etching using the separated blocking layer areas 20a′ as a barrier.

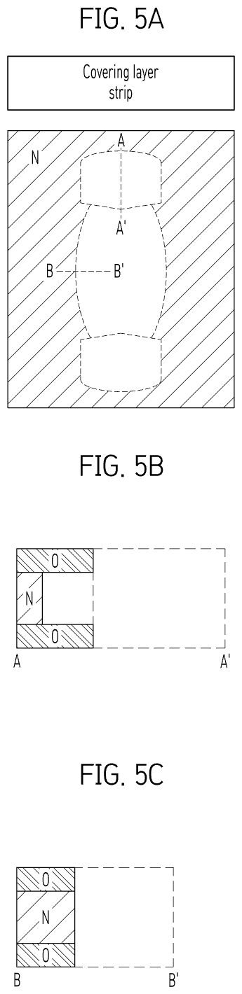

After the tier nitride recess process, any remaining sacrificial blocking layer 20a′ is removed by a dry or wet etching process which has enough selectivity between the sacrificial layers and the tier oxide/nitride layers as illustrated in FIGS. 5A, 5B, and 5C.

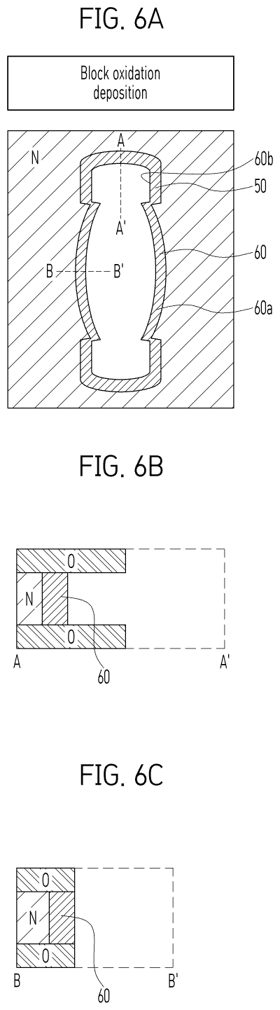

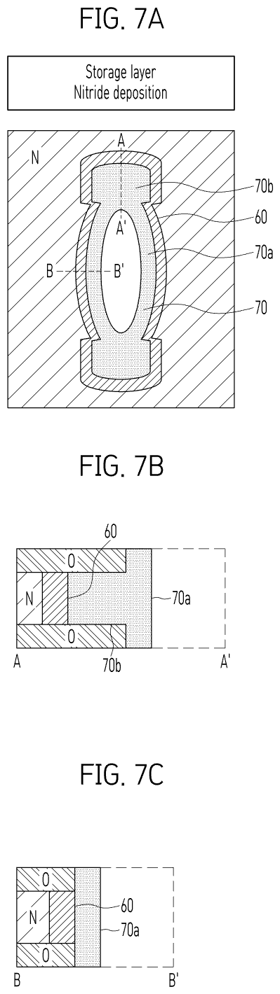

The method further includes depositing in a sequential manner first a blocking oxide layer 60 for electrical insulation from the later formed metal word lines as shown in FIGS. 6A, 6B, and 6C and secondly an additional nitride layer 70 both on the recessed pocket and the pillar sidewall area that functions as a storage node as shown in FIGS. 7A, 7B, and 7C. The additional nitride layer 70 is also referred to as a storage layer 70. The blocking oxide layer 60 may have a section 60a in the channel hole CH and one section 60b in each pocket 40.

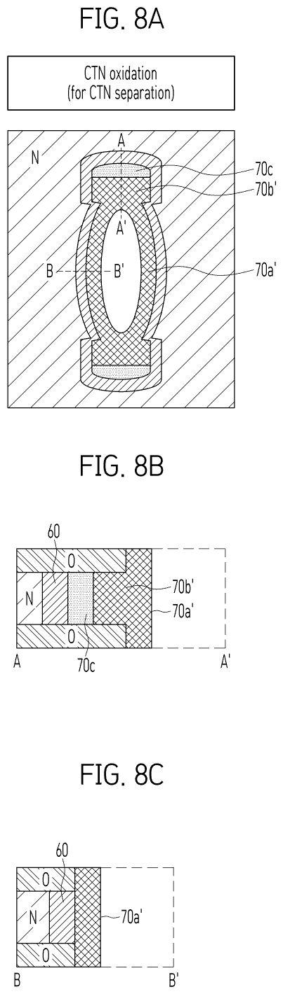

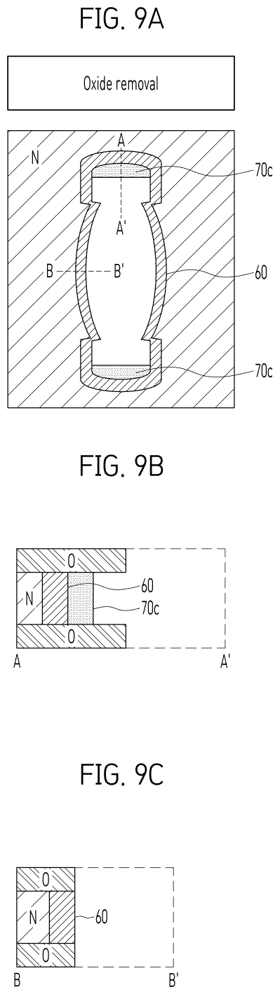

Following the deposition of the additional nitride layer 70 on the pillar sidewall, the method may further include performing additional oxidation and wet or dry etching which has enough selectivity between the tier oxide and nitride for removing the remaining nitride from areas other than a portion of each of the pocket areas. This way each physically separated storage layer can function as an individual cell. More specifically, following the deposition of the nitride layer on the pillar sidewall, an additional oxidation is performed to form an oxide layer as shown in FIG. 8. The oxidation is controlled to convert all of the additional nitride layer 70a that is in the oval section of the channel hole into oxide 70a′ and only a portion of the additional nitride layer 70b in the pockets into an oxide 70b′ in the pockets. Then the formed oxide 70a′ and 70b′ is removed as illustrated in FIG. 9 via selective etching leaving a nitride layer 70c in each of the pocket areas only.

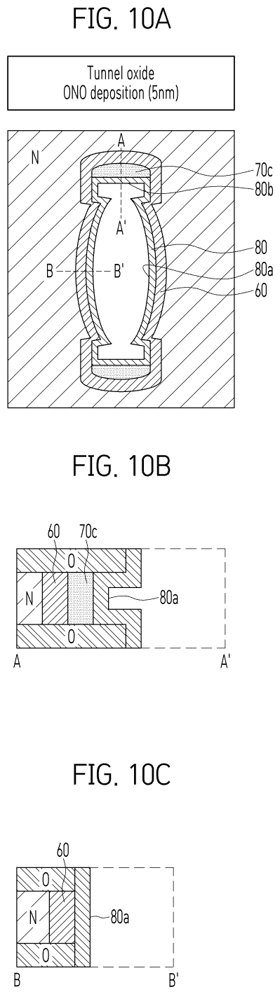

The method may further include adding a tunnel oxide 80 by deposition on the nitride layer in the pocket 40 and in the channel hole as illustrated in FIG. 10. The tunnel oxide in the pocket 40 is designated with numeral 80b and the tunnel oxide in the channel hole is designated with numeral 80a. The tunnel oxide 80a in the channel hole is disposed on the blocking oxide layer 60a. The tunnel oxide 80b in each pocket is disposed on the pocket nitride layer 70c and also on the blocking oxide layer 60b that is exposed by the pocket nitride layer 70c.

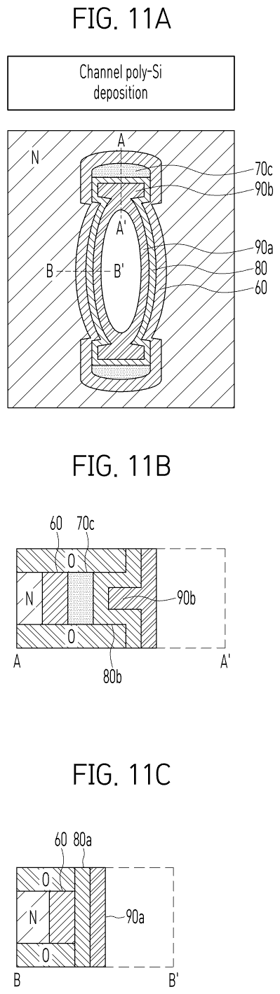

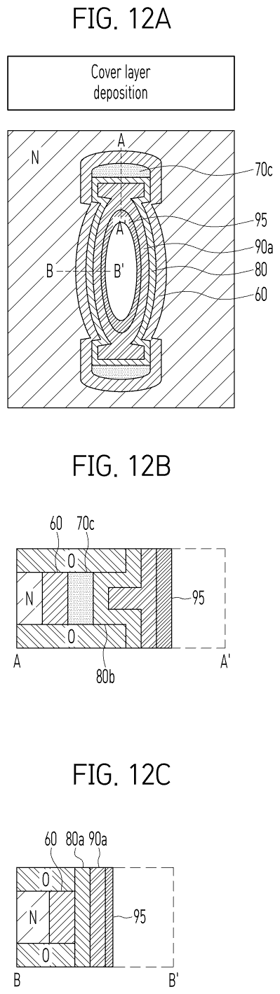

Referring now to FIG. 11, a channel poly-silicon layer 90 (90a, and 90b) may be formed on the tunnel oxide layer to fill the remaining area of the pocket and only fill partially the oval section of the channel structure. The channel poly-silicon layer in the pocket is designated with numeral 90b. The channel poly-silicon in the channel hole is designated with numeral 90a. Referring to FIG. 12 a cover layer 95 may then be added on the poly-silicon layer in the channel hole CH on the channel poly-silicon layer 90a. The cover layer 95 may include a material such as, for example, metal oxide, oxide, nitride, un-doped poly-Si, or metal films as a single, double or triple layers.

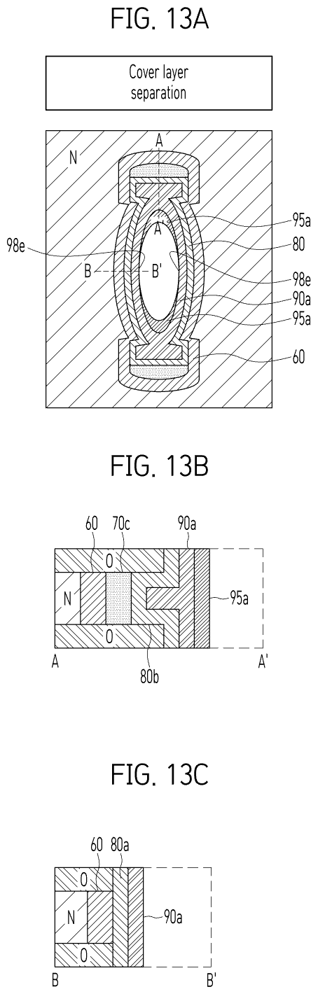

The cover layer 95 may then be separated as shown in FIGS. 13A, 13B, and 13C leaving only two opposite areas of the cover layer 95a that are disposed along the long axis of symmetry of the channel hole CH and exposing the channel poly-silicon layer between the remaining cover layer areas. The exposed areas of the channel poly-silicon generally designated with numeral 98e may be disposed along the short axis of symmetry of the channel hole CH.

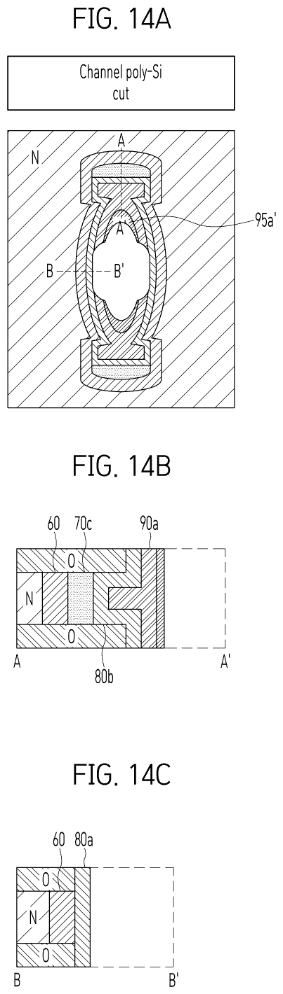

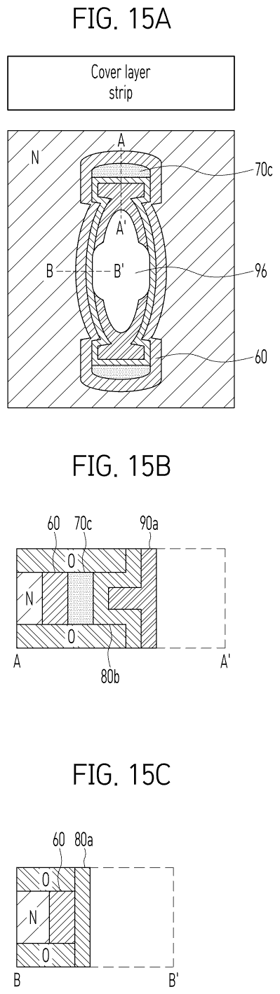

The exposed areas of the poly-silicon layer 98e may then be cut (removed) as shown in FIGS. 14A, 14B and 14C. For example, the exposed areas of the poly-silicon layer 98e may be cut by wet or dry etching. Then, the remaining cover layer 95a from the channel structure may also be removed to form a cross shape opening 96 in the oval section of the channel structure as shown in FIGS. 15A, 15B, and 15C. As can be seen in FIG. 14A, and 15A the cover layer 95a is removed partially in a first operation shown in FIG. 14A and is then completely removed in a second operation shown in FIG. 15A.

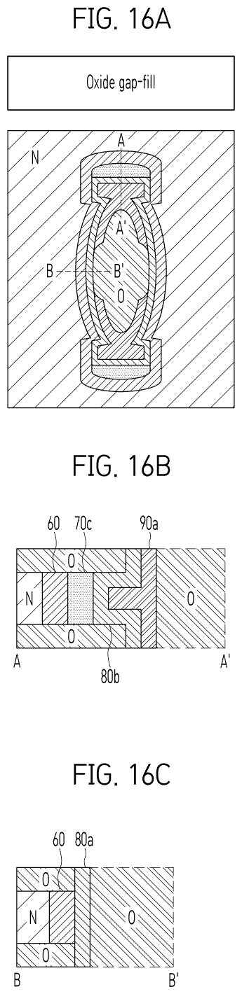

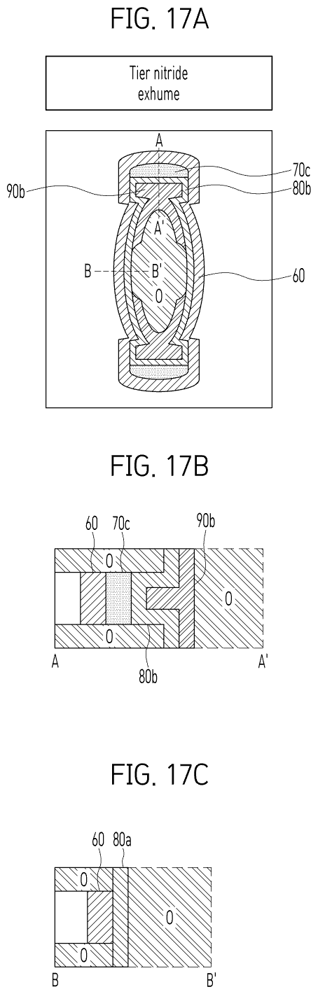

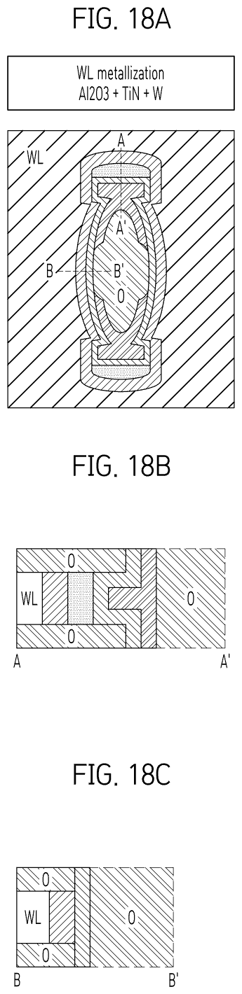

The method may further include gap-filling with an oxide “0” the cross shape opening 96 as shown in FIGS. 16A,16B, and 16C, exhuming the tier nitride as shown in FIGS. 17A, 17B, and 17C, and performing metallization with aluminum oxide (AlO3), TiN and tungsten (“W”) to form word lines as shown in FIGS. 18A, 18B, and 18C. The exhuming of the tier nitride includes removing the nitride by H3PO4 wet cleaning.

Although, the invention has been described in reference to a dual site cell embodiment, the present disclosure generally relates to a method of forming multi-site cells by cutting the storage layer by recessed pocket formation with channel cutting using a sacrificial blocking layer in oval, triangular, and quadruple shapes. The conventional cell structure physically forms one cell per layer on one pillar, but when the storage layer is separated as described, each separated section of a cell can function as an independent cell. Therefore, the present disclosure can dramatically overcome the limitations of vertical scaling in current 3D NAND semiconductor devices. The inventive method allows dividing the recessed pocket-type storage layer (discrete cell) by sacrificial blocking layer (such as non-conformal film deposition) without an oxidation cut process which has some concerns about CTN oxidation during a channel poly-silicon oxidation cut process. The inventive method may secure sufficient storage nodes while improving string current compared to the previous channel-cutting scheme which has smaller areas.

What is claimed is:

1. A method for forming a 3-dimensional memory device with a multi-site cell structure, the method comprising:
providing a stack of alternating oxide layers and nitride layers;
forming a channel hole extending through the stack;
forming a sacrificial blocking layer to partially fill the channel hole; and
separating the sacrificial blocking layer,
wherein the forming of the sacrificial blocking layer includes depositing the sacrificial blocking layer to have a shape with at least two thicker-thickness areas aligned along a short axis of symmetry of the channel hole and at least two thinner-thickness areas aligned along a long axis of symmetry of the channel hole,
wherein the separating of the sacrificial blocking layer includes performing an isotropic etching process at least on the sacrificial blocking layer to separate the two at least two thicker-thickness areas of the sacrificial blocking layer by removing the at least two thinner-thickness areas of the sacrificial blocking layer, and
wherein, after performing the isotropic etching process, the sacrificial blocking layer remains only at the at least two thicker-thickness areas.

2. The method of claim 1, wherein the isotropic etching process includes a wet or dry etching process.

3. The method of claim 2, further comprising recessing the nitride layers.

4. The method of claim 3, wherein the recessing of the nitride layers includes continuing the isotropic etching to remove a portion of the nitride layers adjacent to the channel hole to form a pocket area.

5. The method of claim 4, wherein the recessing of the nitride layers to make the pocket area employs the separated sacrificial blocking layer as a barrier.

6. The method of claim 5, wherein, after the recessing of the nitride layers, the separated sacrificial blocking layer is removed by etching which has selectivity between the separated sacrificial blocking layer and the oxide and nitride layers.

7. The method of claim 6, further comprising sequentially depositing a blocking oxide layer and a storage layer, both on the pocket area and a sidewall area of the channel hole.

8. The method of claim 7, wherein the storage layer is a nitride layer.

9. The method of claim 7, further comprising, after the deposition of the storage layer,
performing oxidation of the storage layer to convert all of the storage layer that is disposed in the channel hole and only a portion of the storage layer that is disposed in the pocket area into an oxidized storage layer while leaving a non-oxidized portion of the storage layer in the pocket area;
removing the oxidized storage layer by selective etching to expose a portion of the blocking oxide layer in the pocket area, the blocking oxide layer on the sidewall of the channel hole, and the non-oxidized portion of the storage layer in the pocket area;
forming a tunnel oxide layer to cover the exposed non-oxidized portion of the storage layer in the pocket area, the blocking oxide layer in the pocket area, and the blocking oxide layer in the channel hole;
forming a channel layer on the tunnel oxide layer to fill a remaining area of the pocket area and partially fill the channel hole;
forming a cover layer on the channel layer with a non-conformal thickness;
separating the cover layer while leaving a remaining cover layer only in at least two thicker thickness areas of the cover layer and exposing the channel layer by removing at least two thinner-thickness areas of the cover layer;
performing a channel layer cut by removing the exposed channel layer; and
stripping the remaining cover layer.

10. The method of claim 9, further comprising, after the removing of the remaining cover layer:
gap-filling the channel hole with an oxide;
exhuming the nitride layers; and
performing metallization in areas where the nitride layers are exhumed to form word lines.

11. A method for forming 3-dimensional memory device with a multi-site cell structure, the method comprising:
providing a stack of alternating oxide layers and nitride layers;
forming a channel hole passing through the stack, the channel hole having an oval cross-section with two opposite wide sides aligned along a short axis of symmetry of the oval shape channel hole and two opposite narrow sides aligned along a long axis of symmetry of the oval shape channel hole;
forming a sacrificial blocking layer having a non-conformal thickness to cover a sidewall of the channel hole;
separating the sacrificial blocking layer; and
recessing the nitride layers by removing a portion of the nitride layers adjacent to the channel hole to form a pocket area,
wherein a thickness of the sacrificial blocking layer at a center of each of the narrow areas of the channel hole is thinner than a thickness of the sacrificial blocking layer at a center of each of the wide areas of the channel hole,
wherein the separating of the sacrificial blocking layer includes performing an isotropic etching process on the sacrificial blocking layer to separate the two thicker-thickness areas of the sacrificial blocking layer by removing the at least two thinner-thickness areas of the sacrificial blocking layer, and
wherein after performing the isotropic etching process, the sacrificial blocking layer remains only at the at least two thicker-thickness areas.

12. The method of claim 11, further comprising recessing the nitride layers by continuing the isotropic etching to remove a portion of the nitride layers adjacent to the channel hole to form a pocket area while using the separated sacrificial blocking layer as a barrier.

13. The method of claim 12, wherein, after the recessing of the nitride layers, the separated sacrificial blocking layer is removed by etching which has selectivity between the separated sacrificial blocking layer and the oxide and nitride layers.

14. The method of claim 13, further comprising sequentially depositing a blocking oxide layer and a storage layer, both on the pocket area and a sidewall area of the channel hole.

15. The method of claim 14, further comprising, after the deposition of the storage layer,
performing oxidation of the storage layer to convert all of the storage layer that is disposed in the channel hole and only a portion of the storage layer that is disposed in the pocket area into an oxidized storage layer while leaving a non-oxidized portion of the storage layer in the pocket area;
removing the oxidized storage layer by selective etching to expose a portion of the blocking oxide layer in the pocket area, the blocking oxide layer on the sidewall of the channel hole, and the non-oxidized portion of the storage layer in the pocket area;
forming a tunnel oxide layer to cover the exposed non-oxidized portion of the storage layer in the pocket area, the blocking oxide layer in the pocket area, and the blocking oxide layer in the channel hole;
forming a channel layer on the tunnel oxide layer to fill a remaining area of the pocket area and partially fill the channel hole;
forming a cover layer on the channel layer with a non-conformal thickness;
separating the cover layer while leaving a remaining cover layer only in at least two thicker thickness areas of the cover layer and exposing the channel layer by removing at least two thinner-thickness areas of the cover layer;
performing a channel layer cut by removing the exposed channel layer; and
stripping the remaining cover layer.

16. The method of claim 15, further comprising, after the stripping of the remaining cover layer:
gap-filling the channel hole with oxide;
exhuming the nitride layers; and
performing metallization in areas where the nitride layers are exhumed to form word lines.
